(19) United States
(12) Patent Application Publication
(10) Pub. No.: US 2025/0048933 A1
(43) Pub. Date: Feb. 6, 2025

(54) MIM ACTUATOR WITH THICK PZT FILM AND HAPTIC DEVICE WITH SUCH AN ACTUATOR

(71) Applicant: LUXEMBOURG INSTITUTE OF SCIENCE AND TECHNOLOGY (LIST), Esch-sur-Alzette (LU)

(72) Inventors: Emmanuel DEFAY, Esch-sur-Alzette (LU); Sebastjan GLINSEK, Esch-sur-Alzette (LU); Song LONGFEI, Esch-sur-Alzette (LU)

(21) Appl. No.: 18/722,621

(22) PCT Filed: Dec. 20, 2022
(86) PCT No.: PCT/EP2022/086910

§ 371 Date: Jun. 21, 2024

(30) Foreign Application Priority Data
Dec. 21, 2021 (LU) LU501047

(51) Int. Cl. H10N 30/078; H10N 30/853

(52) U.S. Cl. CPC H10N 30/078; H10N 30/704; H10N 30/8554

(57) ABSTRACT

A process for manufacturing a MIM structure with a thick film of PZT material. The PZT material is deposited on a substrate by alternative deposition between a PZT slurry and a PZT solution. Additionally, a haptic device comprising a MIM actuator manufactured with such a process.

### CROSS-REFERENCE TO RELATED APPLICATIONS

The present invention is the US national stage under 35 U.S.C. § 371 of International Application No. PCT/EP2022/086910 filed on Dec. 20, 2022, which claims the priority of application LU501047 filed on Dec. 21, 2021, the contents of which (text, drawings and claims) are incorporated here by reference in its entirety.

### FIELD

The invention is directed to the field of microsystem manufacturing and especially the manufacturing of piezoelectric devices obtained by deposition of components on a substrate. The targeted application is haptic devices.

### BACKGROUND

Ferroelectric capacitors on silicon substrate are generally manufactured as a MIM structure: a Metallic bottom electrode, an Insulating layer, and a Metallic top electrode.

The electrodes, made for instance of Pt or AgPd, are separated from one another by an insulating layer which can be a film of Pb(ZrₓTi₁₋ₓ)O₃ (PZT), where 0≤x≤1. The film is generally thin and has a thickness of about 1 μm, which is the customary average value for a deposition made by sol-gel spin coating or inkjet printing.

These MIM actuators may be used in haptic touch devices. The substrate may be excited with a frequency of about 300 Hz to provide haptic feedback to a user. As these MIM actuators have a high capacitance, the power consumption of these devices is high (peak power of about 100 W).

An attempt has been made by the French company “Hap2U” to provide an actuator with a thicker, ceramic based PZT layer (of about 500 μm). However, the use of ceramic involves an expensive deposition process of the PZT on the substrate (by gluing), as the ceramic cannot be deposited by cost-efficient processes (such as sol-gel or inkjet printing, spin coating, etc.). Also, the thickness of the layer of ceramic cannot technically be made thinner, which may become necessary depending on the properties or functionalities that are desired for the film. Finally, the purpose of these thick layers is to alter the mechanical behaviour of the actuator (sensitivity and mechanical deflection).

There is therefore a need to provide a manufacturing method to obtain a haptic actuator that maintains the mechanical properties of existing actuators, while leading to a lower power consumption.

### SUMMARY OF INVENTION

The invention has for technical problem to provide an actuator for a haptic device that leads to a reduced power consumption without having deteriorated properties in terms of deflection or sensibility.

The invention is directed to a method for manufacturing a metal-insulator-metal actuator for a haptic device, the method comprising: (a) providing a substrate; (b) providing a lead zirconate titanate (PZT) solution; (c) preparing a PZT slurry comprising the PZT solution, a nano powder and a surfactant; (d) depositing a layer of PZT solution on the substrate; (e) depositing a layer of PZT slurry on the layer of PZT solution; (f) depositing at least one layer of PZT solution on the layer of PZT slurry; (g) repeating steps (e) and (f) so as to obtain a thick film of PZT material having a combined thickness that is comprised between 1% and 10% of the thickness of the substrate and comprised between about 10 μm and about 100 μm; and (h) depositing a metal patterned electrode on the thick film of PZT material.

It has been established by the inventors that the use of nano-particles-containing PZT slurry enable a capillary effect which enhances the infiltration of PZT solution over the slurry. The solution is thus well distributed through the slurry. The improvement of power consumption while maintaining the same deflection properties is attributed to the combination of three things: (1) this infiltration process; (2) a ratio of thickness between the substrate and the PZT layer; and (3) a thickness of the PZT layer of about 10 μm to 100 μm. We note that “about 10” is to be understood as 9-12 μm and “about 100” is to be understood as 95-105 μm. The infiltration process enables to obtain a thick layer. It has been established by the inventors that the energy required to generate the haptic feedback is inversely proportional to the thickness of the PZT layer (when under similar voltage). However, a too thick layer would have a thickness that is not negligeable in comparison to the substrate and would thus alter the mechanical behaviour of the haptic device, hence the optimal solution with the three features 1 to 3 above. On top of that, it is observed that the absolute values of the thicknesses are a good trade-off between the reduction in power consumption and the amount of time required to produce the actuator. It is also observed that a thick film of 10 μm obtained by another deposition process does not result in the same properties (permittivity, loss tangent) and therefore would not maintain the same amount of deflection for the actuator.

According to an advantageous embodiment, the individual layers of PZT solution and PZT slurry are of such thickness that the steps (e) and (f) are repeated about 7 times to obtain the combined thickness of about 10 μm. These 7 repetitions allow the single layers to be thin enough to rapidly dry between two successive depositions and to obtain a homogenous thick layer. The skilled person understands that about 70 repetitions can be needed to obtain a thickness of about 100 μm.

According to an advantageous embodiment, at each occurrence of step (f), four layers of PZT solution are successively deposited. The voids of the slurry can be completely filled with four layers of PZT and therefore adding more than four layers would deteriorate the efficacy of the deposition process and create inhomogeneities throughout the thickness of the PZT layer.

According to an advantageous embodiment, step (e) comprises spin coating the PZT slurry at a rotational speed of 2000 rpm to 4000 rpm, in various instances at 3000 rpm, and for a duration comprised between 30 and 60 seconds, in various instances during 30 seconds.

According to an advantageous embodiment, the deposition of each layer at step (f) comprises spin coating the PZT solution at a rotational speed of 300 rpm to 700 rpm, in various instances at 500 rpm, and for a duration comprised between 20 and 40 seconds, in various instances during 30 seconds. The capillary effect enables to obtain a good distribution of the solution with this reduced rotation speed.

According to an advantageous embodiment, the rotation of the spinner is delayed by about 30 seconds after the droplets of PZT solution are deposited. The capillary effect acts within these few seconds and allows the solution to spread over the substrate, thereby maximizes the infiltration.

According to an advantageous embodiment, the surfactant is Triton X-100 or polyvinylpyrrolidone.

According to an advantageous embodiment, after step (f), the at least one layer of PZT solution is crystallized at 700° C. for about half an hour.

According to an advantageous embodiment, at step (g), the repetitions of steps (e) and (f) is such as to obtain a thick film of PZT material (10) having a combined thickness that is of about comprised between 1% and 2% of the thickness of the substrate and comprised between about 10 and 20 μm.

According to an advantageous embodiment, after all the layers of PZT have been deposited, the film of PZT is annealed in a furnace at 700° C. for about one hour.

According to an advantageous embodiment, the substrate is a platinized silicon substrate or a fused silica substrate.

The invention also relates to a piezoelectric haptic device comprising an actuator with a thick PZT film, prepared with the method according to any of the preceding claims.

At the microscopic scale, the thick film produced with the alternation of PZT slurry deposition and PZT solution deposition shows a distinctive grain structure that can be observed among others with SEM or X-ray analysis.

At a macroscopic scale, the haptic device of the invention is physically distinct from known haptic devices through both the thickness of the PZT layer and the power consumption for a comparable voltage supply.

According to an advantageous embodiment, the combined thickness of the layer of PZT is of about 10 μm and under a peak-to-peak voltage of 40 V at a frequency of 62 kHz, the actuator consumes a power of about 350 mW.

### BRIEF DESCRIPTION OF THE DRAWINGS

FIG. 1 illustrates the manufacturing process of the invention.

FIG. 2 is a cross-section of the actuator.

FIGS. 3 and 4 are tables showing comparative experiments.

FIGS. 5A and 5B show a comparative graph for PZT layer of similar thickness.

FIG. 6 illustrates the capillary effect.

### DETAILED DESCRIPTION

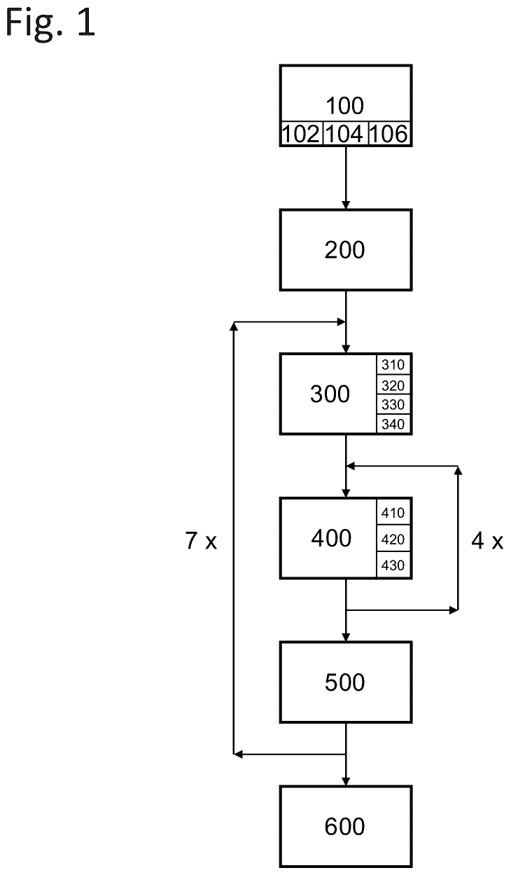

FIG. 1 shows a schematic diagram of a manufacturing method according to the invention.

In a preparation step 100, a substrate is provided 102, as well as a PZT solution 104. A PZT slurry is prepared 106 with PZT nanoparticles.

A first layer of PZT solution is deposited on the substrate in step 200.

After deposition of a layer of PZT slurry (step 300), the deposition of a layer of PZT solution (step 400) can be repeated several times, for example 4 times.

The PZT slurry can be spin-coated at 3000 rpm for 30 s (steps 310), followed by drying at 130° C. (steps 320) and pyrolysis 350° C. (steps 330) on hot plates. Crystallization (steps 340) can be performed at 700° C. for 60 seconds. The PZT solution is then spin-coated at 500 rpm, dried and pyrolyzed in the same conditions as the slurry (steps 410, 420, 430). After a couple of (e.g., four) subsequent deposition-drying-pyrolysis cycles, crystallization (step 500) can happen at 700° C. in air for 30 minutes. The aforementioned steps (300, 400, 500) for PZT deposition can be repeated several times (for instance seven times) to achieve a desired combined thickness (for instance a combined thickness of 10 μm).

A patterned electrode of metal (Pt) can then be deposited (step 600) for ensuring a desired function for the actuator.

The electrode may be patterned using a shadow mask. Platinum electrodes of 500 nm can then be DC-sputtered at room temperature.

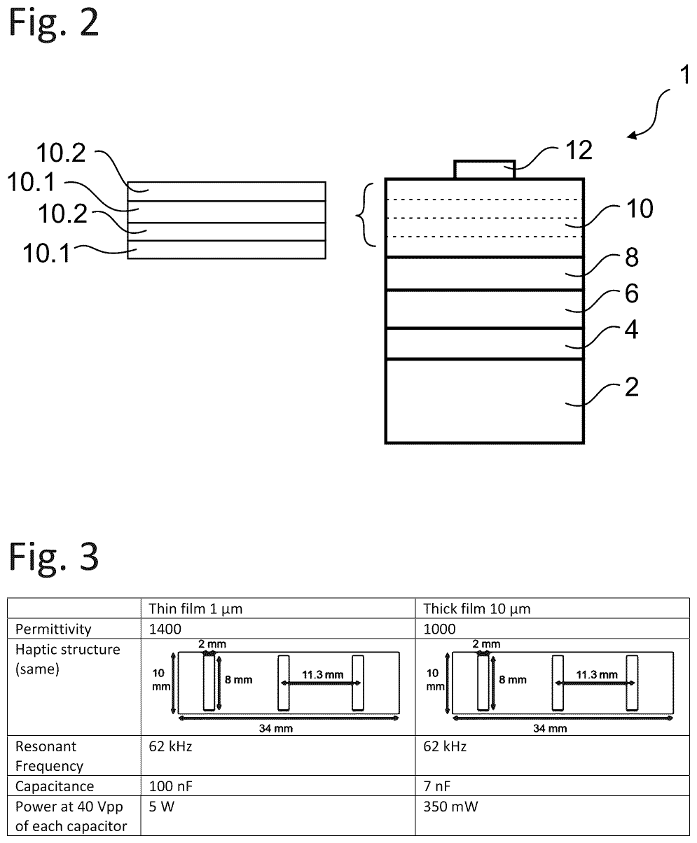

FIG. 2 is a cross-section of the actuator 1 obtained with the method of FIG. 1 (not drawn at scale). The actuator 1 comprises a substrate (2, 4, 6, 8) formed in this example of a platinized silicon substrate. The layers indicated as 2, 4, 6, 8 successively represent 0.65 μm of Si, 500 nm of SiO₂, 20 nm of TiO₂ and 100 nm of Pt.

This substrate is only an example. For instance, the layer 6 (TiO₂) can be replaced with HfO₂; and/or the platinum (layer 8) can be replaced with any other conductor, such as Mo, Au, ITO, etc.; and/or the layers 2, 4 (SiO₂/Si) can be replaced with fused silica glass.

Above the first electrode 8 is deposited a thick layer of PZT 10 (which is about 10 μm). The dotted lines schematically illustrate the various layers of PZT slurry and PZT solution that constitute the PZT thick layer 10. These are also shown on the right-hand side of FIG. 2, with references 10.1 and 10.2 for the various layers. In an advantageous embodiment, two successive layers of PZT slurry 10.1 are separated by 4 layers of PZT solution 10.2.

A second electrode 12 of about 500 nm thick is deposited on the thick layer of PZT 10.

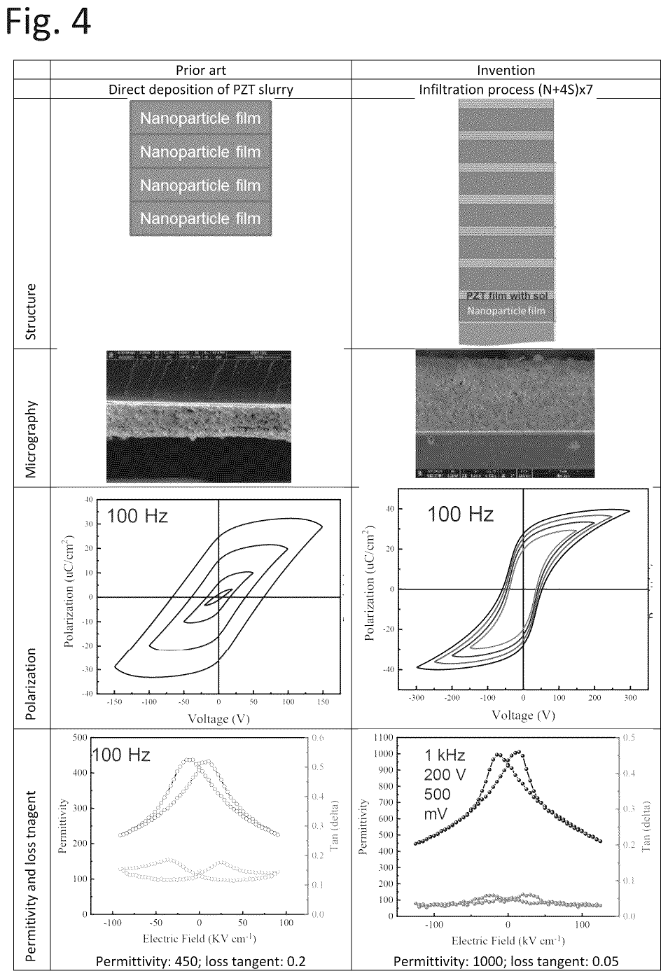

FIG. 3 represents a comparative example. The left-hand side column shows the results for an actuator with a PZT layer of a combined thickness of 1 μm whereas the right-hand side column shows the corresponding values for an actuator with a PZT layer of a combined thickness of 10 μm.

The comparison is carried out by applying a voltage of 40 V peak-to-peak at a frequency of 62 kHz. A vibrometer enables to draw a 2D map of the displacement. The 2D map shows that both actuators have an oscillating displacement of about 3 microns (plus or minus 1.5 microns above and below the resting position). We can thus ensure that the mechanical behaviors of the two actuators are similar.

However, the measured capacitance is higher and the measured power consumption is higher when the thickness of the PZT layer is smaller.

The haptic device of the invention is therefore physically distinct from known haptic devices through both the thickness of the PZT layer and the power consumption for a comparable voltage supply.

FIG. 4 shows a comparative example of the actuator according to the invention (right-hand side column) in comparison with an actuator that is printed with a PZT slurry only (Kwon, DOI: doi.org/10.1016/j.jcrysgro.2006.07.005). One can see that the permittivity is doubled while the loss tangent is divided by four.

The micrographies also show that the grain structure is different: the method of the invention is recognizable, among others, by the grain size, the homogeneity of the distribution of the solution, the reduced number of cavities.

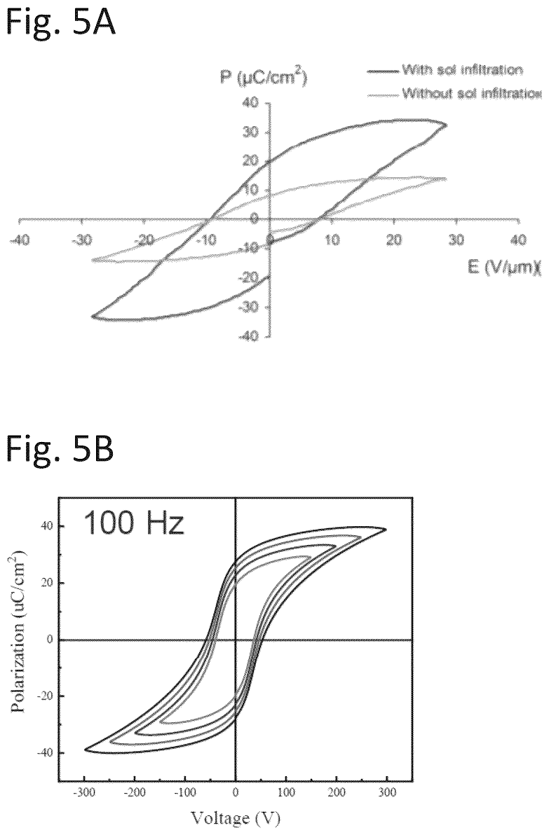

FIGS. 5A and 5B show a comparative graph for PZT layer of similar thickness but prepared with distinct procedures.

FIG. 5A shows the polarization as a function of the voltage for a known actuator (Wang, DOI: 10.1016/j.jeurceramsoc.2011.12.013). One can see a high Ec of 10 V/μm which indicates a high current leak.

By comparison, FIG. 5B shows the polarization as a function of the voltage with an actuator prepared with the method according to the present invention. No current leak is to be seen here.

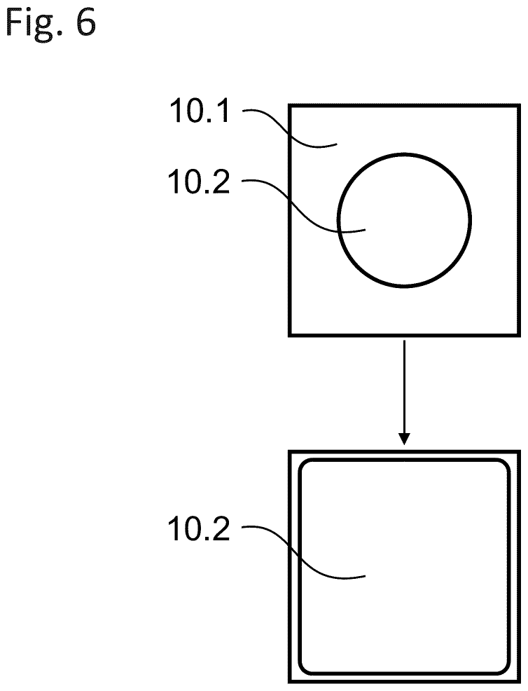

FIG. 6 illustrates the capillary effect that has been observed: when a droplet of PZT solution 10.2 is deposited on a layer of PZT slurry 10.1, the droplet infiltrates and propagates homogeneously onto the PZT slurry within seconds.

Without being bound by theory, the inventors observe that this capillary effect may explain the fact that the power consumption is reduced without altering the deflection of the actuator.

The exemplary embodiments presented above and the various quantities and numbers are given to illustrate the invention. The person skilled in the art would understand that the scope of the invention is only limited by the appended claims and that variations in the amount of dilution, the temperatures or the time duration for the various steps of the method do not depart from the scope of the present invention. For example, variations of about 10% to 20% in the dilution ratios, the duration of the steps, the temperatures or the speed of the spinner can be used.

If the particular application cited above relates to haptic devices, the invention may also provide advantages in other applications, such as ferroelectric devices, non-volatile RAM, memories with pyroelectric readout, piezoelectric applications using electrical cycling under high-amplitude electric fields.

Also, the deposition processes are illustrated as involving spin-coating but alternative deposition processes are possible, such as inkjet printing, etc.

1.-12. (canceled)

13. A method for manufacturing a metal-insulator-metal actuator for a haptic device, the method comprising:
(a) providing a substrate;
(b) providing a lead zirconate titanate (PZT) solution;
(c) preparing a PZT slurry comprising the PZT solution, a nano powder and a surfactant;
(d) depositing a layer of PZT solution on the substrate;
(e) depositing a layer of PZT slurry on the layer of PZT solution;
(f) depositing at least one layer of PZT solution on the layer of PZT slurry, wherein the rotation of the spinner is delayed by about 30 seconds after the droplets of PZT solution are deposited;
(g) repeating steps (e) and (f) so as to obtain a thick film of PZT material having a combined thickness that is comprised between 1% and 10% of the thickness of the substrate and comprised between about 10 μm and about 100 μm; and
(h) depositing a metal patterned electrode on the thick film of PZT material.

14. The method according to claim 13, wherein the individual layers of PZT solution and PZT slurry are of such thickness that the steps (e) and (f) are repeated about 7 times to obtain the combined thickness of about 10 μm.

15. The method according to claim 13, wherein at each occurrence of step (f), four layers of PZT solution are successively deposited.

16. The method according to claim 13, wherein step (e) comprises spin coating the PZT slurry at a rotational speed of 2000 rpm to 4000 rpm for a duration comprised between 30 and 60 seconds.

17. The method according to claim 13, wherein the deposition of each layer at step (f) comprises spin coating the PZT solution at a rotational speed of 300 rpm to 700 rpm, and for a duration comprised between 30 and 60 seconds.

18. The method according to claim 13, wherein the surfactant is Triton X-100 or polyvinylpyrrolidone.

19. The method according to claim 13, wherein after step (f), the at least one layer of PZT solution is crystallized (500) at 700° C. for about half an hour.

20. The method according to claim 13, wherein at step (g), the repetitions of steps (e) and (f) is such as to obtain a thick film of PZT material (10) having a combined thickness that is of about comprised between 1% and 2% of the thickness of the substrate and comprised between about 10 and 20 μm.

21. The method according to claim 13, wherein the substrate is a platinized silicon substrate or a fused silica substrate.

22. A piezoelectric haptic device comprising an actuator with a PZT thick film prepared with the method according to claim 13.

23. The piezoelectric haptic device according to claim 22, wherein the combined thickness of the layer of PZT is of about 10 μm; and under a peak-to-peak voltage of 40 V at a frequency of 62 kHz, the actuator consumes a power of about 350 mW.
